(19) United States
(12) Patent Application Publication
(10) Pub. No.: US 2006/0072641 A1
(43) Pub. Date: Apr. 6, 2006

(54) Semiconductor laser element and monolithic two-wavelength semiconductor laser device

(75) Inventors: Keisuke Miyazaki, Higashihiroshima-shi (JP); Masaki Tatsumi, Mihara-shi (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-shi (JP)

(21) Appl. No.: 11/244,392

(22) Filed: Oct. 6, 2005

(30) Foreign Application Priority Data
Oct. 6, 2004 (JP) 2004-293339

(51) Int. Cl. H01S 5/00

(52) U.S. Cl. 372/46.01; 372/45.01

(57) ABSTRACT

In the semiconductor laser element and the monolithic two-wavelength semiconductor laser device, an active layer 6 is formed above an n-type GaAs substrate 1, and a p-type AlGaInP clad layer 8 is formed above the active layer 6. Furthermore, an n-type AlGaInP block layer 13 having a refractive index nearly equal to that of the p-type AlGaInP clad layer 8 is formed on the side of the ridge portion formed on the p-type AlGaInP clad layer 8.

### CROSS-REFERENCE TO RELATED APPLICATIONS

This nonprovisional application claims a right of priority on the basis of the application No. 2004-293339 filed in Japan on Oct. 6, 2004, under 35 U.S.C. 119(a). The full disclosure of it is incorporated herein by reference.

### BACKGROUND OF THE INVENTION

The present invention relates to a semiconductor laser element and a monolithic two-wavelength semiconductor laser device, and in particular to a self-oscillation type semiconductor laser element and a monolithic two-wavelength semiconductor laser device comprising it.

A semiconductor laser element is mainly used as at least one of a reading light source and a writing light source of an optical disk. In recent years, as a reading semiconductor laser element, a self-oscillation type laser element is widely used, because it is able to effectively avoid the return light noise.

FIG. 6 shows AlGaInP-based red visible light semiconductor laser element of single mode type which does not cause self-oscillation.

In this red visible light semiconductor laser, the thickness of the p-type clad layer 102 formed between the active layer 101 and the GaAs block layer 105 formed on the sides of the ridge portion 103 above the active layer 101 is set to 0.17 μm, and thereby the coefficient of the transverse confinement of light (the difference of refractive index between the ridge portion and the portion other than the ridge portion) Δn is set to 9.85×10⁻³.

FIG. 7 shows a conventional AlGaInP-based self-oscillation type red visible light semiconductor laser.

In this self-oscillation type red visible light semiconductor laser, the thickness of the p-type clad layer 112 formed between the active layer 111 and the GaAs block layer 115 formed on the sides of the ridge portion 113 above the active layer 111 is set to 0.35 μm, and thereby the coefficient of the transverse confinement of light Δn is set to 0.94×10⁻³.

The coefficient of the transverse confinement of light Δn of the self-oscillation type semiconductor laser is less than that of the non-self-oscillation type semiconductor laser, and the transverse confinement of light of the self-oscillation type semiconductor laser is thus more weak than that of the non-self-oscillation type semiconductor laser. From this fact, in the self-oscillation type semiconductor laser, both side regions of the active layer underlying outside the ridge portion are saturatable absorption regions, so that the laser is capable of self-oscillation operation.

However, in order that the above conventional self-oscillation type visible light semiconductor laser has a self-oscillation structure, it is necessary to set the thickness of the p-type clad layer 112 to about two times larger than that of the p-type clad layer 102 of the non-self-oscillation type laser shown in FIG. 6, which causes a problem that the ineffective current which does not contribute to the laser oscillation increases, and the drive current thus becomes large.

### SUMMARY OF THE INVENTION

It is therefore an object of the present invention to provide a self-oscillation type semiconductor laser element capable of decreasing the return light noise and decreasing the drive current to lower the operation cost.

In order to achieve the above object, there is provided a semiconductor laser element comprising:

a substrate;

an active layer formed above the substrate;

an upper clad layer formed on the active layer;

a ridge portion formed above the upper clad layer; and

a layer which is formed at least at a part of the region on the side of the ridge portion and has a refractive index nearly equal to that of the upper clad layer.

The above semiconductor laser element is provided with, above a substrate, a layer which is formed at least at a part of the region on the side of a ridge portion and has a refractive index nearly equal to that of an upper clad layer, so that while keeping the intensity of self-oscillation large as it is, the ineffective current which does not contribute to the laser oscillation can be decreased, thereby decreasing the drive current. Consequently, the return light noise can be lowered, and the drive current can be decreased to lower the operation cost.

In one embodiment of the present invention, the layer having a refractive index nearly equal to that of the upper clad layer is a dielectric layer.

According to the above embodiment, the layer having a refractive index nearly equal to that of the upper clad layer is a dielectric layer, so that the return light noise can be decreased and the operation cost can be decreased.

In one embodiment of the present invention, the layer having a refractive index nearly equal to that of the upper clad layer is an n-type compound semiconductor layer.

According to the above embodiment, the layer having a refractive index nearly equal to that of the upper clad layer is an n-type compound semiconductor layer, so that the return light noise can be decreased and the operation cost can be decreased.

In one embodiment of the present invention, a GaAs layer is formed on the n-type compound semiconductor layer.

In one embodiment of the present invention, the thickness of the GaAs layer is 0.2 μm or less.

According to the above embodiment, the thickness of the GaAs layer is 0.2 μm or less, so that the drive current can be decreased while keeping the intensity of self-oscillation large as it is. Consequently, the return light noise can be decreased and the operation cost can be decreased.

Also, there is provided a monolithic two-wavelength semiconductor laser device comprising a first semiconductor laser element and a second semiconductor laser element sharing a substrate with the first semiconductor element, the ridge portion of the first semiconductor laser element and the ridge portion of the second semiconductor laser element being arranged substantially parallel on the substrate, wherein

the first semiconductor laser element is the above semiconductor laser element, and the second semiconductor is the above semiconductor laser element.

According to the above monolithic two-wavelength semiconductor laser device, two onboard semiconductor laser elements are semiconductor laser elements according to the present invention, so that in each of the two semiconductor laser elements, the return light noise can be significantly reduced and the drive current can be significantly reduced.

Also, there is provided a monolithic two-wavelength semiconductor laser device comprising a first semiconductor laser element and a second semiconductor laser element sharing a substrate with the first semiconductor element, the ridge portion of the first semiconductor laser element and the ridge portion of the second semiconductor laser element being arranged substantially parallel on the substrate, wherein

at least one of the first semiconductor laser element and the second semiconductor laser element is the above semiconductor laser element.

According to the above monolithic two-wavelength semiconductor laser device, either of the first semiconductor laser element and the second semiconductor laser element is a semiconductor laser element according to the present invention, so that in either of the semiconductor laser elements, the return light noise can be significantly reduced and the drive current can be significantly reduced.

In one embodiment of the present invention, the first semiconductor laser element is a semiconductor laser element for at least one of the reading of information from a compact disc and the writing of information to a compact disc, and the second semiconductor laser element is a semiconductor laser element for at least one of the reading of information from a digital versatile disc and the writing of information to a digital versatile disc.

According to the above embodiment, the first semiconductor laser element is used for a compact disc (CD), the drive current of which can be decreased while keeping the intensity of self-oscillation as it is large, and the second semiconductor laser element is used for a digital versatile disc (DVD), the drive current of which can be decreased while keeping the intensity of self-oscillation large as it is.

In a semiconductor laser element according to the present invention, while keeping the intensity of self-oscillation as it is large, the ineffective current which does not contribute to the laser oscillation can be decreased, thereby decreasing the drive current. Consequently, the return light noise can be lowered and the drive current can be decreased to lower the operation cost.

Furthermore, in a monolithic two-wavelength semiconductor laser device according to the present invention, in at least one of the two onboard semiconductor laser elements, the return light noise can be significantly reduced and the drive current can be significantly reduced.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows the layer structure of an AlGaInP-based self-oscillation type red visible light semiconductor laser element according to the first embodiment of the present invention;

FIG. 2 shows the layer structure of an AlGaInP-based self-oscillation type red visible light semiconductor laser element according to the second embodiment of the present invention;

FIG. 3 shows the layer structure of an AlGaInP-based self-oscillation type red visible light semiconductor laser element according to the third embodiment of the present invention;

FIG. 4 is a cross-sectional view of a monolithic two-wavelength semiconductor laser device according to the first embodiment of the present invention;

FIG. 5 is a cross-sectional view of a monolithic two-wavelength semiconductor laser device according to the second embodiment of the present invention;

FIG. 6 shows an AlGaInP-based red visible light semiconductor laser of single mode type which does not cause self-oscillation; and

FIG. 7 shows a conventional AlGaInP-based self-oscillation type red visible light semiconductor laser.

### DETAILED DESCRIPTION OF THE INVENTION

The present invention will be described in detail below on the basis of the embodiments shown in the drawings.

FIG. 1 shows the layer structure of an AlGaInP-based self-oscillation type red visible light semiconductor laser element according to the first embodiment of the present invention.

This semiconductor laser has a structure that an n-type GaAs buffer layer 2 having the thickness of 0.2 μm, an n-type GaInP interlayer 3 having the thickness of 0.25 μm, an n-type AlGaInP clad layer 4 having the thickness of 1.1 μm, a non-doped AlGaInP guide layer 5 having the thickness of 0.04 μm, an active layer 6 of multi quantum well (MQW) structure consisting of a non-doped GaInP well layer having the thickness of 0.01 μm and a non-doped AlGaInP barrier layer having the thickness of 0.005 μm, a non-doped AlGaInP guide layer 7 having the thickness of 0.04 μm, a p-type AlGaInP clad layer 8 having the thickness of 0.17 μm as an example of an upper clad layer, a p-type GaInP etching stop layer 9 having the thickness of 0.01 μm, a p-type AlGaInP clad layer 10 having the thickness of 0.8 μm, a p-type GaInP interlayer 11 having the thickness of 0.05 μm, and a p-type GaAs cap layer 12 having the thickness of 0.5 μm are successively laminated on a GaAs substrate 1.

The p-type AlGaInP clad layer 10, p-type GaInP interlayer 11, and p-type GaAs cap layer 12 constitute a ridge portion which is a waveguide. The ridge portion is formed by etching both sides of the rectangular p-type GaAs cap layer, p-type GaInP interlayer, and p-type AlGaInP clad layer. The width of the ridge portion is set to 3.8 μm.

Furthermore, on the p-type GaInP etching stop layer 9 locating on both sides of the ridge portion, an n-type AlGaInP block layer 13 is formed which is an example of a layer having a refractive index nearly equal to that of the upper clad layer 8. The refractive index of the n-type AlGaInP block layer 13 is nearly equal to that of the p-type AlGaInP clad layer 8. The n-type AlGaInP block layer 13 consists of a main portion having a substantially trapezoid section, the surface of which is substantially parallel with the surface of the GaAs substrate 1, and a side portion which is connected to the main portion and is formed on the side of the ridge portion. The thickness of the n-type AlGaInP block layer 13 is set to 0.18 μm. Furthermore, on the main portion of the n-type AlGaInP block layer 13 and on the side portion of it, an n-type GaAs layer 14 having the thickness of 1.1 μm is formed.

The composition ratios of Al, Ga, In and P in the n-type AlGaInP block layer 13 are set to the same values as those in the p-type AlGaInP clad layer 8 and in the AlGaInP clad layer 10, and the coefficient of the transverse confinement of light an is nearly equal to the conventional value.

In this connection, the p-type GaInP etching stop layer 9 formed between the p-type AlGaInP clad layer 8 and the n-type AlGaInP block layer 13 is composed not so as to absorb the emitted light from the active layer having a specified wavelength, and thus does not affect the Δn. Furthermore, in the production process, when the n-type AlGaInP block layer 13 and the n-type GaAs layer 14 override the top face of the ridge portion, the overriding portions are removed by the subsequent photolithography process and etching, so that the n-type AlGaInP block layer 13 and the n-type GaAs layer 14 do not override the top face of the ridge portion. The ridge portion structure may, of course, be made using not etching but selective growth.

A p-side ohmic electrode 15 is formed on the ridge portion, n-type AlGaInP block layer 13, and n-type GaAs layer 14, while an n-side ohmic electrode 17 is formed on the surface opposite from the ridge portion side of the GaAs substrate 1.

In detail, by forming an AuZn layer, in which zinc is mixed as impurities with a gold base, on the ridge portion by sputter deposition, and by forming an MoAu layer on the whole surface by sputter deposition, the p-side ohmic electrode 15 is formed on the ridge portion, n-type AlGaInP block layer 13, and n-type GaAs layer 14. In addition, a p-side plating electrode 16 having the thickness of 3 μm for absorbing the distortion, etc. which would be generated in mounting process is formed on the p-side ohmic electrode 15. Furthermore, the GaAs substrate is polished or etched to make the thickness of the wafer about 100 μm, and then an n-side electrode 17 is formed on the surface opposite to the ridge portion side of the GaAs substrate 1.

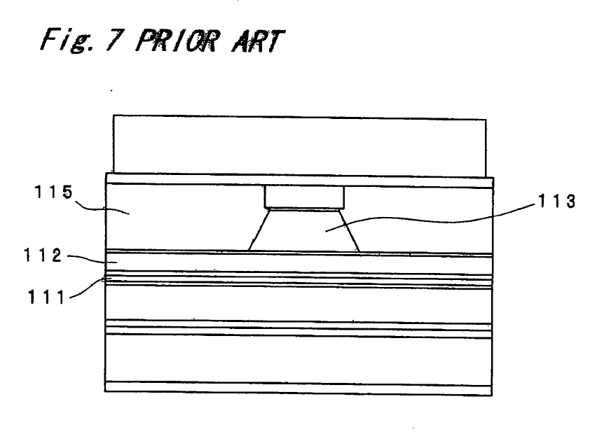

The intensity of self-oscillation, the coherence a at the optical output of 4 mW, and the coherence a at 70° C. of the semiconductor laser element of the first embodiment are nearly equal to those of the conventional AlGaInP-based self-oscillation type red light laser, in which the thickness of the p-type clad layer is 0.35 μm, shown in FIG. 7, while the drive current at the optical output of 4 mW under room temperature of the semiconductor laser element of the first embodiment is 48 mA, in contrast to 55 mA for the conventional semiconductor laser element.

In the above embodiment, the n-type AlGaInP block layer 13 having a refractive index nearly equal to that of the p-type AlGaInP clad layer 8 is formed on the sides of the ridge portion above the p-type AlGaInP clad layer 8, and the thicknesses of the p-type AlGaInP clad layer 8 and n-type AlGaInP block layer 13 are set to about 0.18 μm, so that the coefficient of the transverse confinement of light Δn can be kept to the same level as the conventional one to realize self-oscillation, and the ineffective current can be reduced to decrease the drive power by 10% or more as compared with the conventional semiconductor laser element. Consequently, the return light noise can be lowered and the operation cost can be significantly reduced.

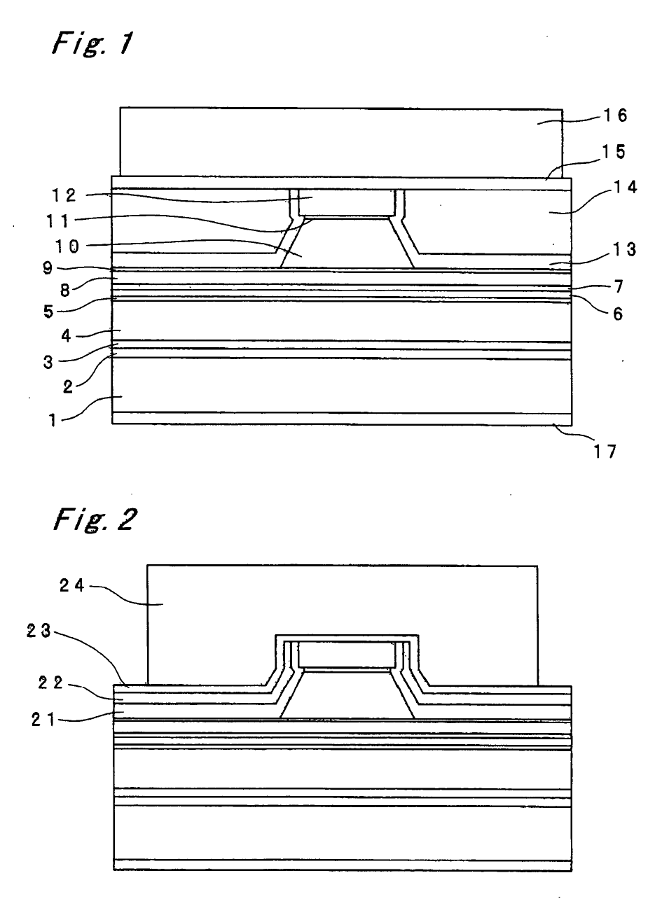

FIG. 2 shows the layer structure of an AlGaInP-based self-oscillation type red visible light semiconductor laser element according to the second embodiment of the present invention.

In the semiconductor laser element of the second embodiment, the thickness of the n-type GaAs layer 22 formed between the p-side electrode 23 and the n-type AlGaInP block layer 21 which is an example of a layer having a refractive index nearly equal to that of the upper clad layer is significantly thin as compared with that of the first embodiment. In detail, in the second embodiment, the n-type GaAs layer 22 having the thickness of 0.1 μm is formed on the n-type AlGaInP block layer 21 having the thickness of 0.18 μm, and then the p-side electrodes 23, 24 are formed in the same way as the first embodiment.

In the semiconductor laser element of the second embodiment in which the thickness of the n-type GaAs layer 22 on the AlGaInP block layer 21 is thin as compared with the first embodiment, the Δn is low, the transverse confinement of light is weak, and the intensity of self-oscillation is large as compared with the first embodiment, while the drive current is nearly equal to that of the semiconductor laser element of the first embodiment.

In addition, it was proved by experiment that when the thickness of the n-type GaAs layer on the AlGaInP block layer is set to 0.2 μm or less, the drive current can be reduced while keeping the intensity of self-oscillation nearly equal to that of the first embodiment by adjusting the composition ratios and thickness of each of the layers to obtain an optimum Δn, and consequently the operation cost can be more reduced.

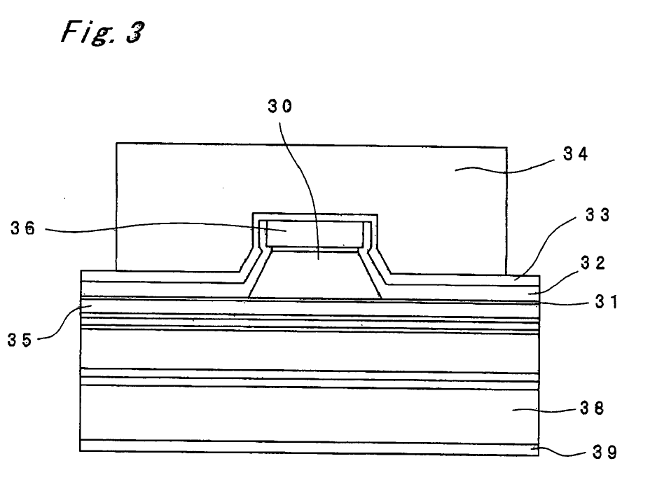

FIG. 3 shows the layer structure of an AlGaInP-based self-oscillation type red visible light semiconductor laser element according to the third embodiment of the present invention.

In the semiconductor laser element of the third embodiment, a dielectric film having the same refractive index as that of the p-type AlGaInP clad layer 8 or p-type AlGaInP clad layer 13 in the first embodiment, such as an Si dielectric layer 32 having the thickness of 0.18 μm which is an example of a layer having a refractive index nearly equal to that of the upper clad layer, is formed on the p-type GaInP etching stop layer 31 locating on both sides of the ridge portion. The Si dielectric layer 32 has a Δn reducing role and a current constriction role. In this connection, in the production process, when the Si dielectric layer overrides the top face of the ridge portion, the overriding portion is removed by the subsequent photolithography process and etching.

On the Si dielectric layer 32, a p-side ohmic electrode having a constant thickness and a p-side plating electrode 34 are successively formed. In detail, AuZn is evaporated onto the ridge portion 30 (onto the p-type GaAs cap layer 36) which is a current path, while Mo/Au sputter deposition is carried out on the whole surface, to form a p-side electrode 33. Furthermore, a plating electrode 34 having the thickness of 3 μm is formed on the p-side electrode 33 for the purpose of absorbing the distortion, etc. which would be generated in mounting process. Furthermore, the GaAs substrate 38 is polished or etched to make the thickness of the wafer about 100 μm, and then an n-side electrode 39 is formed on the surface opposite from the ridge portion side of the GaAs substrate 38.

In the semiconductor laser element of the third embodiment, the Si dielectric film 32 having a refractive index nearly equal to that of the p-type AlGaInP clad layer 35 which is an example of an upper clad layer is formed, and an absorbing region such as an Mo electrode or Au electrode is formed on the Si dielectric film 32, so that while keeping the Δn, that is, the intensity of self-oscillation nearly equal to that of the conventional semiconductor laser element, the drive current can be significantly reduced.

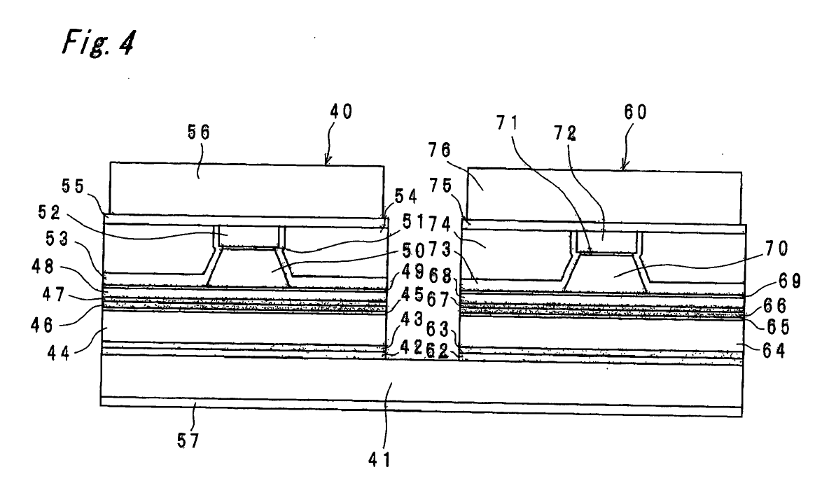

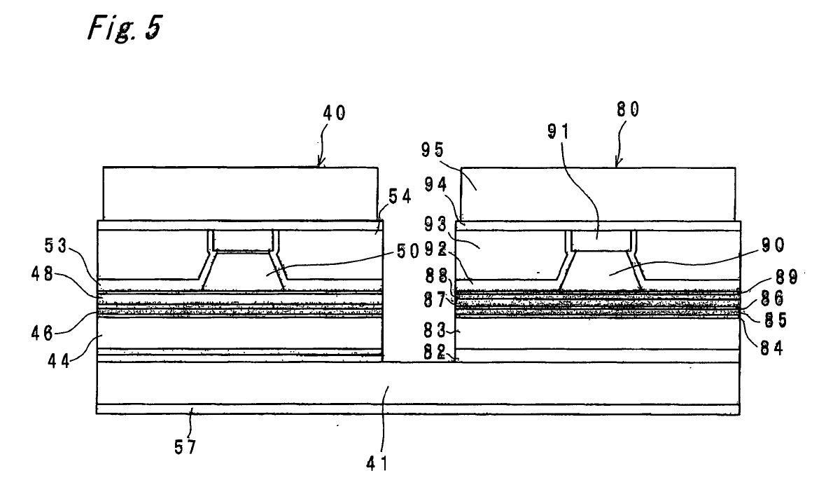

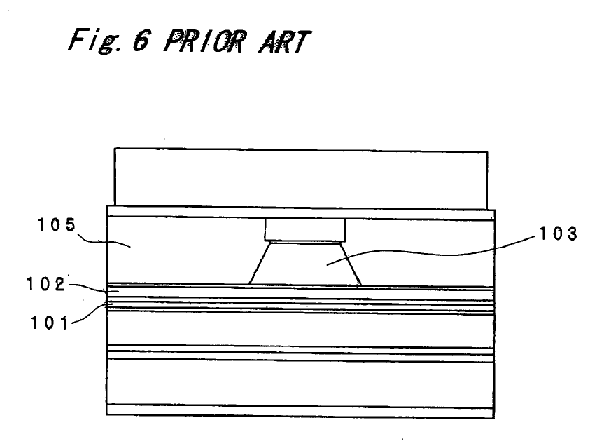

FIG. 4 is a cross-sectional view of a monolithic two-wavelength semiconductor laser device according to the first embodiment of the present invention. The monolithic two-wavelength semiconductor laser device has a structure that a semiconductor laser element for DVD use 40 for reading the information written on a DVD, and a semiconductor laser element for CD use 60 for reading the information written on a CD are arranged in parallel on an n-type GaAs substrate 41.

The semiconductor laser element for DVD use 40 has the same structure as the semiconductor laser element of the first embodiment.

In detail, the semiconductor laser element for DVD use 40 has a structure that an n-type GaAs buffer layer 42, an n-type GaInP interlayer 43, an n-type AlGaInP clad layer 44, a non-doped AlGaInP guide layer 45, an active layer 46 of multi quantum well structure consisting of a non-doped GaInP well layer and a non-doped AlGaInP barrier layer, a non-doped AlGaInP guide layer 47, a p-type AlGaInP clad layer 48 which is an example of an upper clad layer, a p-type GaInP etching stop layer 49, a p-type AlGaInP clad layer 50, a p-type GaInP interlayer 51, and a p-type GaAs cap layer 52 are successively laminated on the GaAs substrate 41.

The p-type AlGaInP clad layer 50, p-type GaInP interlayer 51, and p-type GaAs cap layer 52 constitute a ridge portion which is a waveguide. The ridge portion 50 is formed by etching both sides of the rectangular p-type GaAs cap layer 52, p-type GaInP interlayer 51, and p-type AlGaInP clad layer 50.

Furthermore, on the p-type GaInP etching stop layer 49 locating on both sides of the ridge portion, an n-type AlGaInP block layer 53 is formed which is an example of a layer having a refractive index nearly equal to that of the upper clad layer. The refractive index of the n-type AlGaInP block layer 53 is nearly equal to that of the p-type AlGaInP clad layer 48. The n-type AlGaInP block layer 53 consists of a main portion having a substantially trapezoid section, the surface of which is substantially parallel with the surface of the GaAs substrate 41, and a side portion which is connected to the main portion and is formed on the side of the ridge portion. Furthermore, on the main portion of the n-type AlGaInP block layer 53 and on the side portion of it, an n-type GaAs layer 54 is formed.

The composition ratios of Al, Ga, In and P in the n-type AlGaInP block layer 53 are set to the same values as those in the p-type AlGaInP clad layer 48 and in the AlGaInP clad layer 50. That is, the coefficient of the transverse confinement of light Δn is nearly equal to the conventional value.

A p-side ohmic electrode 55 and a p-side plating electrode 56 are successively formed on the n-type AlGaInP block layer 53 and n-type GaAs layer 54. Furthermore, an n-side ohmic electrode 57 is formed on the surface opposite to the ridge portion side of the GaAs substrate 41.

On the other hand, the semiconductor laser element for CD use 60 has a structure that an n-type GaAs buffer layer 62, an n-type GaInP interlayer 63, an n-type AlGaInP clad layer 64, a non-doped AlGaAs guide layer 65, an active layer 66 of multi quantum well structure consisting of a non-doped AlGaAs well layer and a non-doped AlGaAs barrier layer, a non-doped AlGaAs guide layer 67, a p-type AlGaInP clad layer 68 which is an example of an upper clad layer, a p-type GaInP etching stop layer 69, a p-type AlGaInP clad layer 70, a p-type GaInP interlayer 71, and a p-type GaAs cap layer 72 are successively laminated on the GaAs substrate 41.

The p-type AlGaInP clad layer 70, p-type GaInP interlayer 71, and p-type GaAs cap layer 72 constitute a ridge portion which is a waveguide. The ridge portion is formed by etching both sides of the rectangular p-type GaAs cap layer, p-type GaInP interlayer, and p-type AlGaInP clad layer.

Furthermore, on the p-type GaInP etching stop layer locating on both sides of the ridge portion, an n-type AlGaInP block layer 73 is formed which is an example of a layer having a refractive index nearly equal to that of the upper clad layer 68. The n-type AlGaInP block layer 73 consists of a main portion having a substantially trapezoid section, the surface of which is substantially parallel with the surface of the GaAs substrate 41, and a side portion which is connected to the main portion and is formed on the side of the ridge portion. Furthermore, on the main portion of the n-type AlGaInP block layer 73 and on the side portion of it, an n-type GaAs layer 74 is formed.

The composition ratios of Al, Ga, In and P in the n-type AlGaInP block layer 73 are set to the same values as those in the p-type AlGaInP clad layer 68 and in the AlGaInP clad layer 70, so that the coefficient of the transverse confinement of light Δn is nearly equal to the conventional value.

In this connection, the p-type GaInP etching stop layer 69 formed between the p-type AlGaInP clad layer 68 and the n-type AlGaInP block layer 73 has a composition of not absorbing the emitted light from the active layer having a specified wavelength, and thus does not affect the Δn. Furthermore, in the production process, when the n-type AlGaInP block layer 73 and the n-type GaAs layer 74 override to the top face of the ridge portion, the overriding portions are removed by the subsequent photolithography process and etching, so that the n-type AlGaInP block layer 73 and the n-type GaAs layer 74 do not override the top face of the ridge portion. The ridge portion structure may, of course, be made using not etching but selective growth.

A p-side ohmic electrode 75 is formed on the n-type AlGaInP block layer 73 and n-type GaAs block layer 74, while an n-side electrode 57 is formed on the surface opposite from the ridge portion side of the GaAs substrate 41.

In detail, by an AuZn layer, in which zinc is mixed as impurities with a gold base, on the ridge portion by sputter deposition, and by forming an MoAu layer on the whole surface by sputter deposition, the p-side ohmic electrode 75 is formed on the ridge portion, n-type AlGaInP block layer 73, and n-type GaAs layer 74. In addition, a p-side plating electrode 76 having the thickness of 3 μm for absorbing the distortion, etc. which would be generated in mounting process is formed on the p-side ohmic electrode 75. Furthermore, the GaAs substrate is polished or etched to make the thickness of the wafer about 100 μm, and then an n-side electrode 57 is formed on the surface opposite from the ridge portion side of the GaAs substrate 41.

In this monolithic two-wavelength semiconductor laser device, the ridge portion of the semiconductor laser element for DVD use 40 has the same composition as the ridge portion of the semiconductor laser element for CD use 60, and the ridge portion of the semiconductor laser element for DVD use 40 and the ridge portion of the semiconductor laser element for CD use 60 are simultaneously etched. Even if the composition of the semiconductor laser element for DVD use is different from that of the semiconductor laser element for CD use, it is possible to perform photolithography process at the same time for both of the semiconductor elements and etch them to form the ridge portions.

Furthermore, in this monolithic two-wavelength semiconductor laser device, the n-type AlGaInP block layer 53 of the semiconductor laser element for DVD use 40 and the n-type AiGaInP block layer 73 of the semiconductor laser element for CD use 60 both having the same thickness of 0.18 μm are simultaneously grown, and the n-type GaAs layer 54 of the semiconductor laser element for DVD use 40 and the n-type GaAs layer 74 of the semiconductor laser element for CD use 60 are simultaneously grown.

After the n-type AlGaInP block layers 53 and 73 are simultaneously grown, and then the n-type GaAs layers 54 and 74 are simultaneously grown, in order to prevent current leakage in the whole area of the block layers, etching for separating the n-type block layers between the semiconductor laser element for DVD use 40 and the semiconductor laser element for CD use 60 is performed by photolithography process and etching process.

Furthermore, when the electrodes of the semiconductor laser element for DVD use 40 and semiconductor laser element for CD use 60 are formed, the p-side electrodes are formed by being separated between the laser elements 40 and 60, and the n-side electrode is formed after polishing the n-side substrate.

Furthermore, in this monolithic two-wavelength semiconductor laser device, the thickness of the p-type AlGaInP clad layer 48 of the semiconductor laser element for DVD use 40 and the thickness of the p-type AlGaInP clad layer 68 of the semiconductor laser element for CD use 60 are both set to 0.17 μm, and the n-type AlGaInP block layers 53 and 73 having the thickness of 0.18 μm are formed on the sides of their respective ridge portions, so that each of the semiconductor laser elements is capable of self-oscillation.

In this monolithic two-wavelength semiconductor laser device, the structure of the semiconductor laser element for DVD use 40 is identical to that of the semiconductor laser element of the first embodiment, so that in the semiconductor laser element for DVD use 40, the return light noise can be reduced and the drive power can be reduced.

Furthermore, in this monolithic two-wavelength semiconductor laser device, also in the CD-side, Δn can be lowered like the DVD-side, and the regions of the active layer locating on both sides of the ridge portion can be made a saturatable absorption region. Consequently, also in the CD-side, the transverse confinement of light of the active layer can be made weak, thereby realizing self-oscillation operation allowing the return light noise to be reduced and allowing the drive power to be reduced.

Furthermore, in this monolithic two-wavelength semiconductor laser device, the composition ratios of Al, Ga, In, and P in the p-type AlGaInP clad layer 48 are equal to those in the AlGaInP clad layer 50 of the semiconductor laser element for DVD use 40, and the composition ratios of Al, Ga, In, and P in the p-type AlGaInP clad layer 68 are equal to those in the AlGaInP clad layer 70 of the semiconductor laser element for CD use 60.

However, all we need is that the refractive index of the p-type AlGaInP clad layer 48 is equal to that of the AlGaInP clad layer 50 of the semiconductor laser element for DVD use, and the refractive index of the p-type AlGaInP clad layer 60 is equal to that of the AlGaInP clad layer 70 of the semiconductor laser element for CD use. Also in this case, in both of the laser elements, self-oscillation operation allowing the return light noise to be reduced and allowing the drive power to be reduced can be realized.

Furthermore, in the semiconductor laser element for DVD use 40 and the semiconductor laser element for CD use 60, even if the n-type AlGaInP block layers 53 and 73 are substituted with AlGaAs block layers having the same refractive index, the same operation and effect as those of the above embodiment can be obtained.

FIG. 5 is a cross-sectional view of a monolithic two-wavelength semiconductor laser device according to the second embodiment of the present invention.

The structure of the semiconductor laser element for DVD use of the second embodiment is identical to that for DVD use of the first embodiment.

The monolithic two-wavelength semiconductor laser device of the second embodiment is different from that of the first embodiment only in the structure of the semiconductor laser element for CD use 80.

Description about portions of the monolithic two-wavelength semiconductor laser device of the second embodiment having the same constitution as those of the first embodiment will be omitted with the portions being marked by the same reference numerals of the first embodiment. Also, description about the same operation and effect of the monolithic two-wavelength semiconductor laser device of the second embodiment as those of the first embodiment will be omitted, but only the operation and effect different from those of the first embodiment will be described.

In the semiconductor laser element for DVD use 40 of the monolithic two-wavelength semiconductor laser device of the second embodiment, the n-type AlGaInP block layer 53 having the same refractive index as that of the p-type AlGaInP clad layer 48 and AlGaInP clad layer 50 is formed on the side of the ridge portion to set the Δn to an appropriate value and lower the coefficient of the transverse confinement of light, so that the regions of the active layer locating on both sides of the ridge portion is used as a saturatable absorber to achieve self-oscillation.

On the other hand, the structure of the semiconductor laser element for CD use 80 is as follows. That is, an n-type GaAs buffer layer 82, an n-type AlGaAs clad layer 83, a non-doped AlGaAs guide layer 84, an active layer 85 consisting of a non-doped AlGaAs well layer and an AlGaAs barrier layer (MQW), a non-doped AlGaAs guide layer 86, a p-type AlGaAs clad layer 87 which is an example of an upper clad layer, a p-type AlGaAs layer 88, and a p-type GaAs etching stop layer 89 are successively laminated on an n-type GaAs substrate 41.

Furthermore, a ridge portion consisting of a p-type AlGaAs clad layer 90 and a p-type GaAs cap layer 91 is formed on the p-type GaAs etching stop layer 89. Furthermore, on the area of the p-type GaAs etching stop layer 89 where no ridge portion is formed and on the side face of the ridge portion, an n-type AlGaInP block layer 92 is formed which is an example of layer having a refractive index nearly equal to that of the upper clad layer 87, and an n-type GaAs layer 93 is formed on the n-type AlGaInP block layer 92 and on the side portion of it.

Furthermore, a p-side electrode 94 is formed on the n-type AlGaInP block layer 92 and n-type GaAs layer 93, and a p-side plating electrode 95 is formed on the p-side electrode 94,

The semiconductor laser element for CD use 80 is provided with the p-type AlGaAs layer 88 and the p-type GaAs etching stop layer 89 between the p-type AlGaAs clad layer 87 and the p-type AlGaAs clad layer 90, thereby being capable of self-oscillation.

In this monolithic two-wavelength semiconductor laser device, after the ridge portion of the semiconductor laser element for DVD use 40 and the ridge portion of the semiconductor laser element for CD use 80 are formed, the n-type AlGaInP block layer 53 having the thickness of 0.18 μm and the n-type GaAs layer 54 are grown on the side of the ridge portion of the semiconductor laser element for DVD use 40.

Furthermore, the refractive indexes of the n-type AlGaAs clad layer 83 and p-type AlGaAs clad layer 87 on both sides of the active layer 85 of the semiconductor laser element for CD use 80 are set to values higher than the refractive indexes of the n-type AlGaInP clad layer 44 and p-type AlGaInP clad layer 48 on both sides of the active layer 46 of the semiconductor laser element for DVD use 40, respectively. From this fact, the n-type AlGaInP block layer 53 can be of real refractive index structure, so that the amount of absorption can be reduced, thus reducing the drive current.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A semiconductor laser element comprising:
a substrate;
an active layer formed above the substrate;
an upper clad layer formed on the active layer;
a ridge portion formed above the upper clad layer; and
a layer which is formed at least at a part of the region on the side of the ridge portion and has a refractive index nearly equal to that of the upper clad layer.

2. The semiconductor laser element as claimed in claim 1, wherein the layer having a refractive index nearly equal to that of the upper clad layer is a dielectric layer.

3. The semiconductor laser element as claimed in claim 1, wherein the layer having a refractive index nearly equal to that of the upper clad layer is an n-type compound semiconductor layer.

4. The semiconductor laser element as claimed in claim 3, wherein a GaAs layer is formed on the n-type compound semiconductor layer.

5. The semiconductor laser element as claimed in claim 4, wherein the thickness of the GaAs layer is 0.2 μm or less.

6. A monolithic two-wavelength semiconductor laser device comprising a first semiconductor laser element and a second semiconductor laser element sharing a substrate with the first semiconductor element, the ridge portion of the first semiconductor laser element and the ridge portion of the second semiconductor laser element being arranged substantially parallel on the substrate, wherein
the first semiconductor laser element is a semiconductor laser element as claimed in claim 1, and the second semiconductor laser element is a semiconductor laser element as claimed in claim 1.

7. A monolithic two-wavelength semiconductor laser device comprising a first semiconductor laser element and a second semiconductor laser element sharing a substrate with the first semiconductor element, the ridge portion of the first semiconductor laser element and the ridge portion of the second semiconductor laser element being arranged substantially parallel on the substrate, wherein
at least one of the first semiconductor laser element and the second semiconductor laser element is a semiconductor laser element as claimed in claim 1.

8. The monolithic two-wavelength semiconductor laser device as claimed in claim 6, wherein
the first semiconductor laser element is a semiconductor laser element for at least one of the reading of information from a compact disc and the writing of information to a compact disc, and the second semiconductor laser element is a semiconductor laser element for at least one of the reading of information from a digital versatile disc and the writing of information to a digital versatile disc.
